(19) United States
(12) Patent Application Publication
(10) Pub. No.: US 2025/0275391 A1
(43) Pub. Date: Aug. 28, 2025

(54) DISPLAY DEVICE

(71) Applicant: LG Display Co., Ltd., Seoul (KR)

(72) Inventors: Youngtaek HONG, Gangneung-si (KR); Miso KIM, Goyang-si (KR)

(73) Assignee: LG Display Co., Ltd., Seoul (KR)

(21) Appl. No.: 18/888,476

(22) Filed: Sep. 18, 2024

(30) Foreign Application Priority Data
Feb. 28, 2024 (KR) 10-2024-0028746

(51) Int. Cl. H10K 59/131; H10K 59/40; H10K 59/80; H10K 77/10; H10K 102/00

(52) U.S. Cl. CPC H10K 59/131; H10K 59/40; H10K 59/873; H10K 77/111; H10K 2102/311

(57) ABSTRACT

A display device may include a flexible substrate; a display area; a non-display area; a bending area extending from the non-display area; 1-1-th link lines disposed on the flexible substrate in the non-display area; one or more insulating layers disposed on the 1-1-th link lines; 1-2-th link lines respectively connected to the 1-1-th link lines through a plurality of first contact holes disposed in the one or more insulating layers; a first planarization layer disposed on the 1-2-th link lines; 1-3-th link lines respectively connected to the 1-2-th link lines through second contact holes disposed in the first planarization layer; and first pads connected to the 1-3-th link lines, where the second contact holes are disposed more adjacent to the display area than the plurality of first contact holes. Thus, a corrosion resistance may be improved.

### CROSS-REFERENCE TO RELATED APPLICATIONS

This application claims the benefit of and priority to Korean Patent Application No. 10-2024-0028746 filed on Feb. 28, 2024, the entire contents of which are incorporated herein by reference for all purposes.

### BACKGROUND

### 1. Technical Field

The present disclosure relates to a display device, and more particularly to, for example, without limitation, a display device including a bending area with an improved corrosion resistance.

### 2. Description of the Related Art

In recent years, a display device has been manufactured by forming light emitting elements, lines, etc. on a substrate made of a material having flexibility, such as plastic. Thus, the display device may display an image even when it is bent like paper. Accordingly, the display device has received attention as a next-generation display device, and research and development thereof have actively been conducted.

However, due to the recent development of display technology, the display device becomes lighter and thinner and the resolution of the product is improved as the number of data is increased. As a result, the number of lines connected to a driver integrated circuit (IC) and the number of pads corresponding to each line are increased. Inevitably, a bezel area becomes wide. Accordingly, technologies for reducing the size of the bezel area by bending a part of the bezel area have been developed.

The description of the related art should not be assumed to be prior art merely because it is mentioned in or associated with this section. The description of the related art includes information that describes one or more aspects of the subject technology, and the description in this section does not limit the invention.

### SUMMARY

An aspect to be achieved by the present disclosure is to provide a display device with an improved corrosion resistance of a plurality of link lines in a non-display area.

Another aspect to be achieved by the present disclosure is to provide a display device in which a defect in reliability caused by a voltage difference between a plurality of link lines may be minimized.

Aspects of the example embodiment of the present disclosure are not limited to the above-mentioned aspects, and other aspects, which are not mentioned above, may be clearly understood by those skilled in the art from the present disclosure.

According to an aspect of the present disclosure, a display device comprises a flexible substrate; a display area; a non-display area; a bending area extending from the non-display area; a plurality of 1-1-th link lines disposed on the flexible substrate in the non-display area; one or more insulating layers disposed on the plurality of 1-1-th link lines; a plurality of 1-2-th link lines respectively connected to the plurality of 1-1-th link lines through a plurality of first contact holes disposed in the one or more insulating layers; a first planarization layer disposed on the plurality of 1-2-th link lines; a plurality of 1-3-th link lines respectively connected to the plurality of 1-2-th link lines through a plurality of second contact holes disposed in the first planarization layer; and a plurality of first pads connected to the plurality of 1-3-th link lines, wherein the plurality of second contact holes is disposed more adjacent to the display area than the plurality of first contact holes.

Other detailed matters of the example embodiments are included in the detailed description and the drawings.

According to one or more aspects of the present disclosure, an organic layer contact hole is disposed in a non-display area so as to be more adjacent to a display area than an inorganic layer contact hole without an increase in size of a bezel area. Thus, a moisture permeation path may be increased.

According to one or more aspects of the present disclosure, a corrosion resistance in the non-display area may be improved.

According to one or more aspects of the present disclosure, it is possible to suppress a resistance increase and an abnormal operation. Thus, reliability of a display device may be improved.

The effects according to the present disclosure are not limited to the contents described above for illustration, and more various effects are included in the present specification.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a schematic plan view of a display device according to an example embodiment of the present disclosure;

FIG. 2 is a cross-sectional view illustrating a bending state of the display device according to an example embodiment of the present disclosure;

FIG. 3 is a cross-sectional view of a pixel in the display device according to an example embodiment of the present disclosure;

FIG. 4 is an enlarged plan view of an area A of FIG. 1;

FIG. 5 is a cross-sectional view taken along the line V-V′ of FIG. 4;

FIG. 6 is an enlarged plan view of an area B of FIG. 1;

FIG. 7 is a cross-sectional view taken along the line VII-VII′ of FIG. 6;

FIG. 8 is an enlarged plan view of a display device according to another example embodiment of the present disclosure; and

FIG. 9 is a cross-sectional view taken along the line IX-IX′ of FIG. 8.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, components, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, components, sections, members, parts, regions, areas, portions, and/or the like) are described using any of the terms such as “on,” “on a top of,” “upon,” “on top of,” “over,” “under,” “above,” “upper,” “at an upper portion,” “at a upper side,” “below,” “lower,” “at a lower portion,” “at a lower side,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “upper,” “lower,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “following,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like (e.g., 1-1-th, 1-2-th, 1-3-th, 2-1-th, 2-2-th, 2-3-th) may be used herein to describe various elements (e.g., layers, films, components, sections, members, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like (e.g., 1-1-th, 1-2-th, 1-3-th, 2-1-th, 2-2-th, 2-3-th) may be used. These terms are intended to identify the corresponding element(s) from the other element(s), and these are not used to define the essence, basis, order, or number of the elements.

The expression that an element (e.g., layer, film, component, lens, electrode, filter, section, member, part, region, area, portion, or the like) “is engaged” with another element may be understood, for example, as that the element may be either directly or indirectly engaged with the another element. The term “is engaged” or similar expressions may refer to a term such as “covers,” “surrounds,” “is in contact,” “overlaps,” “crosses,” “intersects,” “is connected,” “is coupled,” “is attached,” “is adhered,” “is combined,” “is linked,” “is provided,” “is disposed,” “interacts,” or the like. The engagement may involve one or more intervening elements disposed or interposed between the element and the another element, unless otherwise specified. Further, the element may be engaged at least partially or entirely (or completely) with the another element, unless otherwise specified. Further, the element may be included in at least one of two or more elements that are engaged with each other. Similarly, the another element may be included in at least one of two or more elements that are engaged with each other. When the element is engaged with the another element, at least a portion of the element may be engaged with at least a portion of the another element. The term “with another element” or similar expressions may be understood as “another element,” or “with, to, in, or on another element,” as appropriate by the context. Similarly, the term “with each other” may be understood as “each other,” or “with, to, or on each other,” as appropriate by the context.

The phrase “through” may be understood, for example, to be at least partially through or entirely through.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements. Further, “at least some,” “some,” “some elements,” “a portion,” “portions,” “at least a portion,” “at least portions,” “a part,” “at least a part,” “parts,” “at least parts,” “one or more,” or the like of the plurality of elements can represent (i) one element of the plurality of elements, (ii) a part of the plurality of elements, (iii) parts of the plurality of elements, (iv) multiple elements of the plurality of elements, or (v) all of the plurality of elements. Moreover, “at least some portions,” “some,” “at least some parts,” “a portion,” “portions,” “at least a portion,” “at least portions,” “a part,” “at least a part,” “parts,” “at least parts,” or the like of an element can represent (i) a portion (or a part) of the element, (ii) one or more portions (or parts) of the element, or (iii) the element, or all portions of the element.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise. In one or more aspects, unless stated otherwise, the term “nth” may refer to “nnd” (e.g., 2nd where n is 2), or “nrd” (e.g., 3rd where n is 3), and n may be a natural number.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

A phrase “substantially the same” or “nearly the same” may indicate a degree of being considered as being equivalent to each other taking into account minute differences due to errors in the manufacturing process.

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

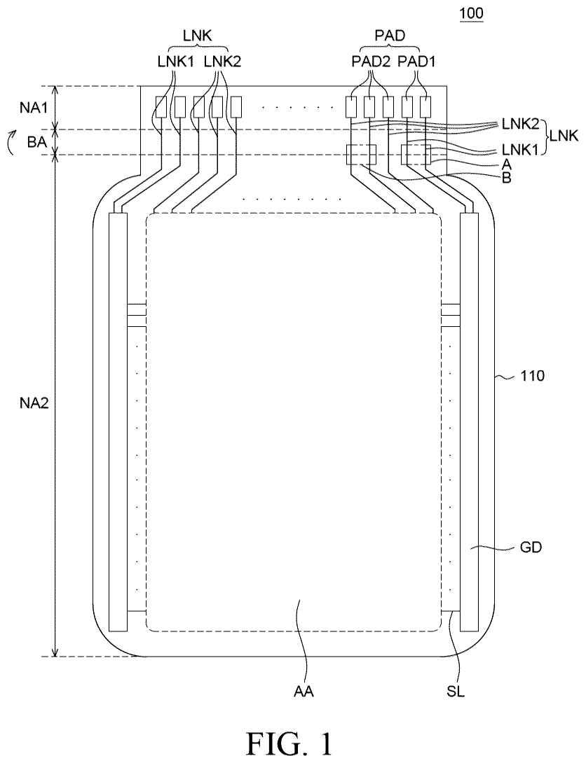

FIG. 1 is a schematic plan view of a display device according to an example embodiment of the present disclosure. FIG. 1 illustrates only a flexible substrate 110, a plurality of pads PAD, a plurality of link lines LNK, a plurality of scan lines SL, and a gate driver GD among various components of a display device 100 for convenience in explanation.

Referring to FIG. 1, the flexible substrate 110 includes a display area AA, a non-display area NA, and a bending area BA extending from the non-display area NA.

The flexible substrate 110 is a base member for supporting various components of the display device 100 and may be made of an insulating material. For example, the flexible substrate 110 may be made of a material having flexibility. The flexible substrate 110 may be made of a plastic material such as polyimide (PI) or the like.

The flexible substrate 110 may have variant corner regions. The display area AA may correspond in shape to the variant corner regions of the flexible substrate 110. The corners of the flexible substrate 110 and the corners of the display area AA may each have a round shape. However, the present disclosure is not limited thereto. The flexible substrate 110 and the display area AA may have various shapes suitable for the design of an electronic device employing the display device 100.

The display area AA is an area in which images are displayed. A plurality of pixels is disposed in the display area AA. A driving unit for driving a plurality of light emitting elements configured to display images may be disposed in the display area AA. For example, if the display device 100 is an organic light emitting display device, the plurality of light emitting elements may organic light emitting elements each including an anode, an organic layer, and a cathode. The driving unit may include various components such as a power line, a gate line, a data line, a thin film transistor, and a storage capacitor which serve to drive the organic light emitting elements. Hereinafter, for convenience in description, the description will be made under the assumption that the display device 100 is an organic light emitting display device. However, the display device 100 is not limited to the organic light emitting display device.

The non-display area NA is an area in which no image is displayed. Various lines and circuits for driving the light emitting elements in the display area AA are disposed in the non-display area NA. For example, the gate driver GD, a data driver, the link lines LNK, the plurality of pads PAD, and the like may be disposed in the non-display area NA. The non-display area NA in which no image is displayed may be a bezel area, but example embodiments of the present disclosure are not limited thereto.

The non-display area NA may be an area extending from the display area AA. However, the present disclosure is not limited thereto. The non-display area NA may be an area that encloses the display area AA.

The non-display area NA includes a first non-display area NA1, the bending area BA, and a second non-display area NA2. The second non-display area NA2 is an area extending from the display area AA. The bending area BA is an area extending from the second non-display area NA2. The bending area BA may be bent in a direction as indicated by arrows of FIG. 1. The first non-display area NA1 is an area extending from the bending area BA.

The gate driver GD, the plurality of pads PAD, and the like may be disposed in the first non-display area NA1. The plurality of pads PAD includes various link lines and pads connected to a flexible film or a printed circuit board.

The plurality of pads PAD includes a plurality of first pads PAD1 and a plurality of second pads PAD2. The plurality of first pads PAD1 is located on both sides of the flexible substrate 110 in the first non-display area NAL. The plurality of second pads PAD2 is located at the center of the flexible substrate 110 in the first non-display area NAL. For example, the plurality of second pads PAD2 may be located between the plurality of first pads PAD1.

The plurality of first pads PAD1 is electrically connected to a plurality of first link lines LNK1 of the plurality of link lines LNK. The plurality of first link lines LNK1 may be connected to the gate driver GD.

The plurality of second pads PAD2 is electrically connected to a plurality of second link lines LNK2 of the plurality of link lines LNK. The plurality of second link lines LNK2 may be connected to the data line, the power line, etc. disposed in the display area AA.

The gate driver GD supplies a plurality of scan signals to the plurality of scan lines SL in response to a plurality of gate control signals supplied from a timing controller. FIG. 1 illustrates that one gate driver GD is disposed on one side of a display panel as being spaced apart from the display panel. However, the number and disposition of gate drivers GD are not limited thereto.

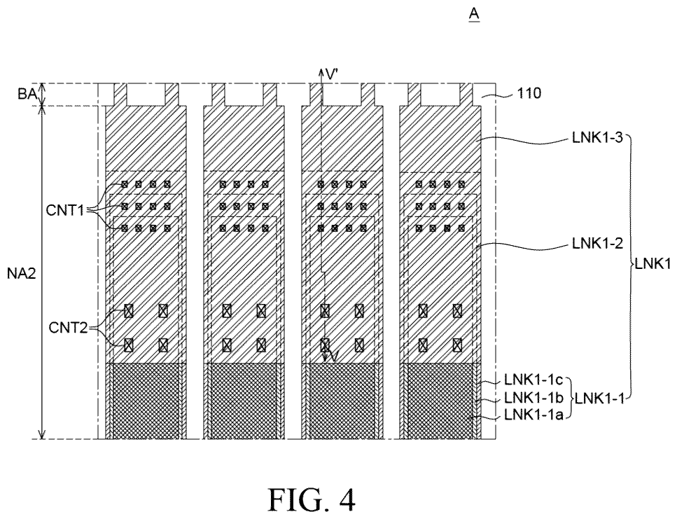

The second non-display area NA2 is an area enclosing the bending area BA and the display area AA. The plurality of link lines LNK, such as a gate link line, a power link line, a data link line, etc., may be disposed in the second non-display area NA2. That is, the second non-display area NA2 serves to transmit signals from the plurality of pads PAD to the display area AA. If the flexible substrate 110 has variant corner regions, the second non-display area NA2 may correspond in shape to the flexible substrate 110 and the display area AA. Meanwhile, the plurality of link lines LNK will be described in detail with reference to FIG. 4 through FIG. 7.

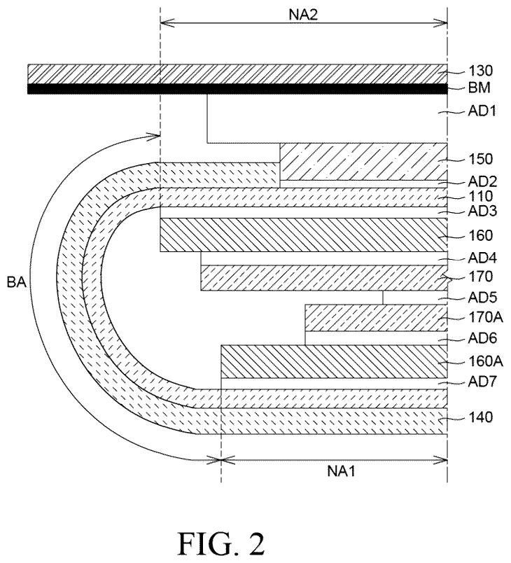

FIG. 2 is a cross-sectional view illustrating a bending state of the display device according to an example embodiment of the present disclosure. For convenience in explanation, FIG. 2 does not illustrate various components disposed on the flexible substrate 110, but illustrates only the flexible substrate 110.

Referring to FIG. 2, the display device 100 according to an example embodiment of the present disclosure may include a first adhesive layer AD1, a second adhesive layer AD2, a polarizing plate 150, a black matrix BM, a cover window 130, and a micro-coating layer 140 disposed on the flexible substrate 110. Also, the display device 100 may include a third adhesive layer AD3, a fourth adhesive layer AD4, a fifth adhesive layer AD5, a sixth adhesive layer AD6, a back plate 160, and a metal plate 170 disposed under the flexible substrate 110.

Referring to FIG. 2, the cover window 130 is disposed on a front surface of the flexible substrate 110. The cover window 130 may be exposed from the outside of the display device 100, and may protect the display device 100 from external impacts and scratches. Also, the cover window 130 may protect the display device 100 from moisture or the like permeating from the outside. The cover window 130 may be made of glass or a plastic material having flexibility, but is not limited thereto.

The black matrix BM is disposed under the cover window 130. The black matrix BM may be disposed outside the cover window 130 along the circumference of the cover window 130. In this case, the black matrix BM may be disposed corresponding to the second non-display area NA2. The black matrix BM may be made of a material having a low light transmittance. Thus, the black matrix BM may enable various components disposed under the second non-display area NA2 not to be seen from the outside. Also, the black matrix BM may be made of a conductive material and may serve to discharge static electricity of the cover window 130.

The black matrix BM may be made of chrome (Cr), graphite, or resin containing conductive particles. Herein, the resin may be made of one or more of acrylic resin, epoxy resin, phenolic resin, polyamides resin, polyimides resin, unsaturated polyesters resin, polyphenylene resin, polyphenylenesulfides resin, and benzocyclobutene, but is not limited thereto. Also, the conductive particles may be made of one of molybdenum (Mo), chrome (Cr), titanium (Ti), nickel (Ni), neodymium (Nd), copper (Cu), and an alloy of silver (Ag) and magnesium (Mg), but are not limited thereto.

The polarizing plate 150 is disposed between the flexible substrate 110 and the cover window 130. The polarizing plate 150 is disposed on the front surface of the flexible substrate 110. The polarizing plate 150 selectively transmits light to reduce the reflection of external light incident onto the flexible substrate 110. Specifically, various metal materials applied to a semiconductor device, a line, a light emitting element, etc. may be disposed on the flexible substrate 110. Thus, the external light incident onto the flexible substrate 110 may be reflected from the metal material so that the visibility of the display device 100 may be reduced due to the reflection of the external light. Meanwhile, when the polarizing plate 150 is disposed, the polarizing plate 150 may suppress the reflection of the external light to increase the outdoor visibility of the display device 100. However, the polarizing plate 150 may be omitted in some embodiments depending on an implementation of the display device 100, but the present disclosure is not limited thereto.

The first adhesive layer AD1 is disposed between the polarizing plate 150 and the cover window 130, and the second adhesive layer AD2 is disposed between the polarizing plate 150 and the flexible substrate 110. The first adhesive layer AD1 may serve to bond the cover window 130 to the polarizing plate 150, and the second adhesive layer AD2 may serve to bond the polarizing plate 150 to the flexible substrate 110. As a result, the first adhesive layer AD1 and the second adhesive layer AD2 may serve to bond the flexible substrate 110 to the cover window 130. Each of the first adhesive layer AD1 and the second adhesive layer AD2 may be configured as a transparent adhesive layer which allows images to be visible. For example, the first adhesive layer AD1 and the second adhesive layer AD2 may be made of optical clear adhesive (OCA), but are not limited thereto.

The back plate 160 is disposed under the flexible substrate 110. The back plate 160 may be disposed to support the flexible substrate 110. For example, if the flexible substrate 110 is made of a plastic material such as polyimide, an additional component for protecting the substrate may be needed due to flexibility of the substrate 110. Thus, a support substrate made of glass is disposed under the flexible substrate 110 to perform the manufacturing process of the display device 100. After the manufacturing process is completed, the support substrate may be separated to be released. However, even after the support substrate is released, a component for supporting the flexible substrate 110 is needed. Therefore, the back plate 160 for supporting the flexible substrate 110 may be disposed under the flexible substrate 110.

The back plate 160 may contain a plastic material. For example, the back plate 160 may be configured as a plastic thin film made of polyimide (PI), polyethylene naphthalate (PEN), polyethylene terephthalate (PET), or a combination of these polymers.

The third adhesive layer AD3 is disposed between the flexible substrate 110 and the back plate 160. The third adhesive layer AD3 may serve to bond the flexible substrate 110 to the back plate 160. The third adhesive layer AD3 may be made of pressure sensitive adhesive (PSA), but is not limited thereto.

The metal plate 170 is disposed under the back plate 160. The metal plate 170 may protect the components of the display device 100 from external impacts. Also, the metal plate 170 may serve as a ground to suppress static electricity permeating into the display device 100 or easily discharge residual electric charges accumulated in the display device 100 to the outside. Further, the metal plate 170 may easily dissipate heat generated in the display device 100 to the outside. The metal plate 170 may be made of a metal material having excellent heat conductivity, electrical conductivity, and mechanical strength. For example, the metal plate 170 may be made of copper (Cu) or stainless steel (SUS), but is not limited thereto.

The fourth adhesive layer AD4 is disposed between the back plate 160 and the metal plate 170. The fourth adhesive layer AD4 may serve to bond the back plate 160 to the metal plate 170. The fourth adhesive layer AD4 may be made of pressure sensitive adhesive (PSA), but is not limited thereto.

An additional back plate 160A and an additional metal plate 170A are disposed under the metal plate 170 in the first non-display area NA1.

The additional back plate 160A and the additional metal plate 170A may serve to enhance the strength of the first non-display area NA1 of the flexible substrate 110. Meanwhile, the additional back plate 160A and the additional metal plate 170A may be disposed not to overlap the bending area BA. Thus, the thickness of the components disposed in the bending area BA may be minimized, and a neutral plane of the bending area BA may be easily controlled. Therefore, the flexibility of the bending area BA may be secured.

The fifth adhesive layer AD5 is disposed between the metal plate 170 and the additional metal plate 170A. Also, the sixth adhesive layer AD6 is disposed between the additional metal plate 170A and the additional back plate 160A. The fifth adhesive layer AD5 may serve to bond the metal plate 170 to the additional metal plate 170A. Also, the sixth adhesive layer AD6 may serve to bond the additional metal plate 170A and the additional back plate 160A. For example, the fifth adhesive layer AD5 and the sixth adhesive layer AD6 may be made of pressure sensitive adhesive (PSA), but are not limited thereto.

The first non-display area NA1 of the flexible substrate 110 is disposed under the additional back plate 160A. Further, a seventh adhesive layer AD7 is disposed between the additional back plate 160A and the first non-display area NA1 of the flexible substrate 110. The seventh adhesive layer AD7 may serve to bond the additional back plate 160A to the first non-display area NA1 of the flexible substrate 110. For example, the seventh adhesive layer AD7 may be made of pressure sensitive adhesive (PSA), but is not limited thereto.

The micro-coating layer 140 is disposed on the first non-display area NA1, the second non-display area NA2 and the bending area BA of the flexible substrate 110. During bending, the link lines LNK disposed on the flexible substrate 110 may be applied with tensile force, and, thus, micro-cracks may occur. Thus, the micro-coating layer 140 is prepared by coating resin to a small thickness at a bending position and serves to protect the link lines.

The micro-coating layer 140 may be made of resin, such as an acryl-based material or urethane acrylate, but is not limited thereto.

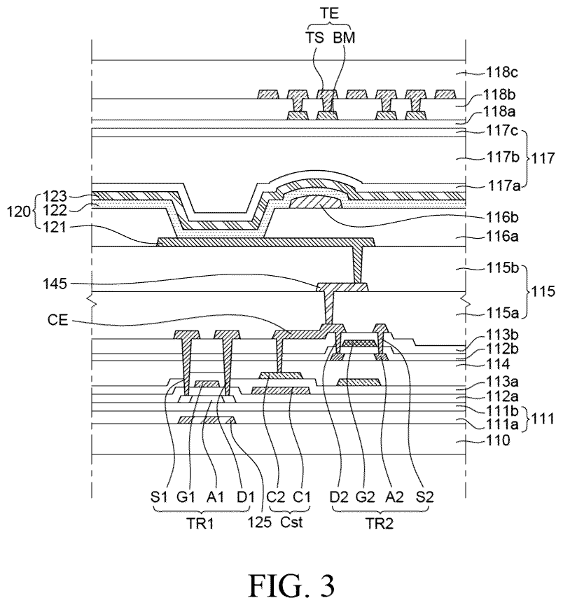

FIG. 3 is a cross-sectional view of a pixel in the display device according to an example embodiment of the present disclosure.

Referring to FIG. 3, the display device 100 according to an example embodiment of the present disclosure may include the flexible substrate 110, a first buffer layer 111, a first thin film transistor TR1, and a second thin film transistor TR2. Also, the display device 100 may include a first gate insulating layer 112a, a first interlayer insulating layer 113a, a second buffer layer 114, a second gate insulating layer 112b, and a second interlayer insulating layer 113b. Further, the display device 100 may include a connection electrode CE, a first planarization layer 115a, a second planarization layer 115b, an auxiliary electrode 145, a bank 116a, a spacer 116b. Furthermore, the display device 100 may include an anode 121, and an emission layer 122, a cathode 123, an encapsulation layer 117, and a touch sensing layer.

The flexible substrate 110 serves to support and protect the components of the display device 100 which are disposed on the flexible substrate 110. The flexible substrate 110 is configured to support various components included in the display device 100, and may be made of an insulating material. For example, the flexible substrate 110 may be a polyimide (PI) substrate, but is not limited thereto.

A light shielding layer 125 may be disposed on the flexible substrate 110.

The first buffer layer 111 may cover the light shielding layer 125 and may be disposed on the flexible substrate 110. Specifically, a multi-buffer layer 111a may be disposed on the flexible substrate 110 to cover the light shielding layer 125, and an active buffer layer 111b may be disposed on the multi-buffer layer 111a.

The multi-buffer layer 111a may retard the permeation of moisture or oxygen into the flexible substrate 110 and contain at least one of silicon nitride (SiNx) and silicon oxide (SiOx).

The active buffer layer 111b may protect a first active layer A1 and block various kinds of defects introduced from the flexible substrate 110. For example, the active buffer layer 111b may contain at least one of a-Si, silicon nitride (SiNx), and silicon oxide (SiOx).

The first thin film transistor TR1 may be disposed on the first buffer layer 111. The first thin film transistor TR1 may include the first active layer A1, a first gate electrode G1, a first source electrode S1, and a first drain electrode D1. Herein, the first source electrode S1 may be a first drain electrode and the first drain electrode D1 may be a first source electrode depending on the design of a pixel circuit.

The first active layer A1 may be disposed on the first buffer layer 111 so as to overlap the light shielding layer 125. The first active layer A1 may contain amorphous silicon or polycrystalline silicon. For example, the first active layer A1 may contain low temperature polycrystalline silicon (LTPS). For example, the polycrystalline silicon material has a high mobility (100 cm²/Vs or more), low energy power consumption and excellent reliability. Thus, it may be applied to a gate driver and/or multiplexer (MUX) for use in a driving element for driving thin film transistors for light emitting elements. Also, it may be applied to the active layer A1 of a driving thin film transistor of the display device 100 according to an example embodiment of the present disclosure. However, the present disclosure is not limited thereto. For example, the polycrystalline silicon material may be applied to an active layer A1 of a switching thin film transistor depending on characteristics of the display device 100. An amorphous silicon (a-Si) material is deposited on the first buffer layer 111, and polycrystalline silicon is formed by a dehydrogenation process and a crystallization process. Then, the first active layer A1 is prepared by patterning the polycrystalline silicon. Herein, the first active layer A1 may include a first channel region in which a channel is formed during driving of the first thin film transistor TR1, and a first source region and a first drain region on both sides of the first channel region. The first source region refers to a portion of the first active layer A1 connected to the first source electrode S1. The first drain region refers to a portion of the first active layer A1 connected to the first drain electrode D1. For example, the first source region and the first drain region may be prepared by ion-doping (impurity-doping) of the first active layer A1. The first source region and the first drain region may be prepared by doping the polycrystalline silicon material with ions. The first channel region may refer to a portion which is not ion-doped, but is left as the polycrystalline silicon material.

The first gate insulating layer 112a may be disposed on the first active layer A1. The first gate insulating layer 112a may be configured by a single layer of silicon nitride (SiNx) or silicon oxide (SiOx) or a multi-layer thereof. The first gate insulating layer 112a may include contact holes. The contact holes serve to respectively connect the first source electrode S1 and the first drain electrode D1 of the first thin film transistor TR1 to the first source region and the first drain region in the first active layer A1 of the first thin film transistor TR1.

The first gate electrode G1 of the first thin film transistor TR1 and a first capacitor electrode C1 of a storage capacitor Cst may be disposed on the first gate insulating layer 112a.

Herein, each of the first gate electrode G1 and the first capacitor electrode C1 may be configured by a single layer made of one of molybdenum (Mo), copper (Cu), titanium (Ti), aluminum (Al), chrome (Cr), gold (Au), nickel (Ni), and neodymium (Nd) or an alloy thereof, or a multi-layer thereof. The first gate electrode G1 may be provided on the first gate insulating layer 112a so as to overlap the first channel region in the first active layer A1 of the first thin film transistor TR1.

The first capacitor electrode C1 may be omitted based on driving characteristics of the display device 100 and the structure and type of the thin film transistor. The first gate electrode G1 and the first capacitor electrode C1 may be prepared by the same process. Also, the first gate electrode G1 and the first capacitor electrode C1 may be made of the same material and provided on the same layer.

The first interlayer insulating layer 113a may be disposed on the first gate insulating layer 112a, the first gate electrode G1, and the first capacitor electrode C1. The first interlayer insulating layer 113a may be configured by a single layer of silicon nitride (SiNx) or silicon oxide (SiOx) or a multi-layer thereof. Further, the first interlayer insulating layer 113a may include contact holes. The contact holes serve to expose the first source region and the first drain region in the first active layer A1 of the first thin film transistor TR1.

A second capacitor electrode C2 of the storage capacitor Cst may be disposed on the first interlayer insulating layer 113a. The second capacitor electrode C2 may be configured by a single layer made of one of molybdenum (Mo), copper (Cu), titanium (Ti), aluminum (Al), chrome (Cr), gold (Au), nickel (Ni), and neodymium (Nd) or an alloy thereof, or a multi-layer thereof. The second capacitor electrode C2 may be provided on the first interlayer insulating layer 113a so as to overlap the first capacitor electrode C1. Also, the second capacitor electrode C2 may be made of the same material as the first capacitor electrode C1. The second capacitor electrode C2 may be omitted based on driving characteristics of the display device 100 and the structure and type of the thin film transistor.

The second buffer layer 114 may be disposed on the first interlayer insulating layer 113a and the second capacitor electrode C2. The second buffer layer 114 may be configured by a single layer of silicon nitride (SiNx) or silicon oxide (SiOx) or a multi-layer thereof. The second buffer layer 114 may include contact holes. The contact holes serve to expose the first source region and the first drain region in the first active layer A1 of the first thin film transistor TR1. Also, the second buffer layer 114 may include a contact hole. The contact hole serves to expose the second capacitor electrode C2 of the storage capacitor Cst.

The second buffer layer 114 may also be configured by a multi-layer, but is not limited thereto.

A second active layer A2 of the second thin film transistor TR2 may be disposed on the second buffer layer 114. Herein, the second thin film transistor TR2 may include the second active layer A2, the second gate insulating layer 112b, a second gate electrode G2, a second source electrode S2, and a second drain electrode D2. Herein, the second source electrode S2 may be a drain electrode and the second drain electrode D2 may be a source electrode depending on the design of a pixel circuit.

Also, the second active layer A2 may include a second channel region in which a channel is formed during driving of the second thin film transistor TR2, and a second source region and a second drain region on both sides of the second channel region. The second source region refers to a portion of the second active layer A2 connected to the second source electrode S2. The second drain region refers to a portion of the second active layer A2 connected to the second drain electrode D2.

The second active layer A2 may be made of an oxide semiconductor. Since an oxide semiconductor material has a larger band gap than a silicon material, electrons may not cross the band gap in an off state, which results in a low off-current. Therefore, the thin film transistor including the active layer made of the oxide semiconductor is suitable for a switching thin film transistor having a short on-time and a long off-time, but is not limited thereto. The thin film transistor may be applied as a driving thin film transistor depending on characteristics of the display device 100. Further, since an auxiliary capacitance is low due to the low off-current, the second active layer A2 is suitable for a high-resolution light emitting element. For example, the second active layer A2 may be made of a metal oxide. The second active layer A2 may be made of various metal oxides such as indium-gallium-zinc-oxide (IGZO). Herein, the description has been made under the assumption that the second active layer A2 of the second thin film transistor TR2 is made of IGZO among various metal oxides. However, the present disclosure is not limited thereto. The second active layer A2 may be made of other metal oxides, such as indium-zinc-oxide (IZO), indium-gallium-tin-oxide (IGTO), or indium-gallium-oxide (IGO), instead of IGZO.

A metal oxide is deposited on the second buffer layer 114, and a heat treatment process is performed for stabilization. Then, the second active layer A2 is prepared by patterning the metal oxide.

The second gate insulating layer 112b may be disposed on the entire flexible substrate 110 including the second active layer A2. For example, the second gate insulating layer 112b may be configured by a single layer of silicon nitride (SiNx) or silicon oxide (SiOx) or a multi-layer thereof.

The second gate electrode G2 may be disposed on the second gate insulating layer 112b.

The second gate electrode G2 may be configured by a single layer made of one of molybdenum (Mo), copper (Cu), titanium (Ti), aluminum (Al), chrome (Cr), gold (Au), nickel (Ni), and neodymium (Nd) or an alloy thereof, or a multi-layer thereof.

For example, a metal material is provided on the second gate insulating layer 112b, and a photoresist pattern is formed on the metal material. Then, the second gate electrode G2 is prepared by wet etching the metal material using the photoresist pattern as a mask. A wet etchant for etching the metal material may contain a material which selectively etches molybdenum (Mo), copper (Cu), titanium (Ti), aluminum (Al), chrome (Cr), gold (Au), nickel (Ni), neodymium (Nd), or an alloy thereof, but does not etch the insulating material.

The second interlayer insulating layer 113b may be disposed on the second gate insulating layer 112b and the second gate electrode G2. The second interlayer insulating layer 113b may include contact holes. The contact holes serve to expose the first active layer A1 of the first thin film transistor TR1 and the second active layer A2 of the second thin film transistor TR2. For example, the second interlayer insulating layer 113b may include contact holes. The contact holes serve to expose the first source region and the first drain region in the first active layer A1 of the first thin film transistor TR1. The second interlayer insulating layer 113b may include contact holes. The contact holes serve to expose the second source region and the second drain region in the second active layer A2 of the second thin film transistor TR2.

The second interlayer insulating layer 113b may be configured by a single layer of silicon nitride (SiNx) or silicon oxide (SiOx) or a multi-layer thereof.

The connection electrode CE, the first source electrode S1 and the first drain electrode D1 of the first thin film transistor TR1, and the second source electrode S2 and the second drain electrode D2 of the second thin film transistor TR2 may be disposed on the second interlayer insulating layer 113b.

The connection electrode CE may be electrically connected to the second drain electrode D2 of the second thin film transistor TR2. Also, the connection electrode CE may be electrically connected to the second capacitor electrode C2 of the storage capacitor Cst through the contact hole formed in the second buffer layer 114 and the second interlayer insulating layer 113b. That is, the connection electrode CE may serve to electrically connect the second capacitor electrode C2 of the storage capacitor Cst to the second drain electrode D2 of the second thin film transistor TR2.

Herein, the first source electrode S1 and the first drain electrode D1 of the first thin film transistor TR1 may be connected to the first active layer A1 of the first thin film transistor TR1 through the contact holes formed in the first gate insulating layer 112a, the first interlayer insulating layer 113a, the second buffer layer 114, and the second interlayer insulating layer 113b.

The second source electrode S2 and the second drain electrode D2 of the second thin film transistor TR2 may be connected to the second active layer A2 through the contact holes formed in the second interlayer insulating layer 113b.

The connection electrode CE, the first source electrode S1 and the first drain electrode D1 of the first thin film transistor TR1, and the second source electrode S2 and the second drain electrode D2 of the second thin film transistor TR2 may be made of the same material by the same process.

For example, each of the connection electrode CE, the first source electrode S1 and the first drain electrode D1 of the first thin film transistor TR1, and the second source electrode S2 and the second drain electrode D2 of the second thin film transistor TR2 may be configured by a single layer made of one of molybdenum (Mo), copper (Cu), titanium (Ti), aluminum (Al), chrome (Cr), gold (Au), nickel (Ni), and neodymium (Nd) or an alloy thereof, or a multi-layer thereof. For example, each of the connection electrode CE, the first source electrode S1 and the first drain electrode D1 of the first thin film transistor TR1, and the second source electrode S2 and the second drain electrode D2 of the second thin film transistor TR2 may have a three-layer structure of titanium (Ti), aluminum (Al), and titanium (Ti), but is not limited thereto.

The connection electrode CE may be connected to and integrated with the second drain electrode D2 of the second thin film transistor TR2, but is not limited thereto.

The first planarization layer 115a may be disposed on the connection electrode CE, the first source electrode S1 and the first drain electrode D1 of the first thin film transistor TR1, the second source electrode S2 and the second drain electrode D2 of the second thin film transistor TR2, and the second interlayer insulating layer 113b.

The first planarization layer 115a may be an organic layer to planarize and protect upper portions of the first thin film transistor TR1 and the second thin film transistor TR2. For example, the first planarization layer 115a may be made of an organic material such as acryl resin, epoxy resin, phenolic resin, polyamide resin, polyimide resin, or the like.

The auxiliary electrode 145 may be disposed on the first planarization layer 115a. The auxiliary electrode 145 may be connected to the second drain electrode D2 of the second thin film transistor TR2 through a contact hole formed in the first planarization layer 115a. The auxiliary electrode 145 may serve to electrically connect the second thin film transistor TR2 to the anode 121. Further, the auxiliary electrode 145 may be configured by a single layer made of one of molybdenum (Mo), copper (Cu), titanium (Ti), aluminum (Al), chrome (Cr), gold (Au), nickel (Ni), and neodymium (Nd) or an alloy thereof, or a multi-layer thereof. The auxiliary electrode 145 may be made of the same material as the second source electrode S2 and the second drain electrode D2 of the second thin film transistor TR2.

The second planarization layer 115b may be disposed on the auxiliary electrode 145 and the first planarization layer 115a. For example, the second planarization layer 115b may be made of an organic material such as acryl resin, epoxy resin, phenolic resin, polyamide resin, polyimide resin, or the like.

A light emitting element 120 may be disposed on the second planarization layer 115b.

The anode 121 may be disposed on the second planarization layer 115b. In this case, the anode 121 may be electrically connected to the auxiliary electrode 145 through a contact hole formed in the second planarization layer 115b. The anode 121 may be made of a metal material.

The display device 100 may be a top emission type in which light emitted from the light emitting element 120 is emitted to above the flexible substrate 110 on which the light emitting element 120 is disposed. In this case, the anode 121 may further include a transparent conductive layer and a reflective layer on the transparent conductive layer. The transparent conductive layer may be made of a transparent conductive oxide such as ITO or IZO. The reflective layer may be made of, for example, silver (Ag), aluminum (Al), gold (Au), molybdenum (Mo), tungsten (W), chrome (Cr) or an alloy thereof.

The bank 116a may be disposed for covering the anode 121. The bank 116a may have an open portion corresponding to an emission area of a sub-pixel. A part of the anode 121 may be exposed through the open portion (hereinafter, referred to as “open area”) of the bank 116a. Herein, the bank 116a may be made of an inorganic insulating material, such as silicon nitride (SiNx) or silicon oxide (SiOx), or an organic insulating material, such as benzocyclobutene-based resin, acryl-based resin, or imide-based resin. However, the present disclosure is not limited thereto. The spacer 116b may be further disposed on the bank 116a.

The emission layer 122 may be disposed in and around the open area of the bank 116a. Therefore, the emission layer 122 may be disposed on the anode 121 exposed through the open area of the bank 116a.

The cathode 123 may be disposed on the emission layer 122.

The light emitting element 120 may be composed of the anode 121, the emission layer 122, and the cathode 123. The emission layer 122 may include a plurality of organic layers.

An encapsulation layer 117 may be located on the above-described light emitting element 120.

The encapsulation layer 117 may have a single layer structure or a multi-layer structure. For example, the encapsulation layer 117 may include a first encapsulation layer 117a, a second encapsulation layer 117b, and a third encapsulation layer 117c.

Herein, each of the first encapsulation layer 117a and the third encapsulation layer 117c may be configured by an inorganic layer, and the second encapsulation layer 117b may be configured by an organic layer. Among the first encapsulation layer 117a, the second encapsulation layer 117b, and the third encapsulation layer 117c, the second encapsulation layer 117b may have the greatest thickness and serve as a planarization layer.

The first encapsulation layer 117a may be disposed on the cathode 123 so as to be most adjacent to the light emitting element 120. The first encapsulation layer 117a may be made of an inorganic insulating material suitable for low temperature deposition. For example, the first encapsulation layer 117a may be made of silicon nitride (SiNx), silicon oxide (SiOx), silicon oxynitride (SiON), or aluminum oxide (Al₂O₃). Since the first encapsulation layer 117a is deposited in a low temperature atmosphere, it is possible to suppress damage to the emission layer 122 containing an organic material, which is vulnerable to a high temperature atmosphere, during the deposition process.

The second encapsulation layer 117b may have a smaller area than the first encapsulation layer 117a. In this case, the second encapsulation layer 117b may be disposed to expose both end points of the first encapsulation layer 117a. The second encapsulation layer 117b may serve to buffer stress generated among layers during bending of the flexible display device and enhance planarization performance.

For example, the second encapsulation layer 117b may be made of an organic insulating material such as acryl resin, epoxy resin, polyimide, polyethylene, or silicon oxycarbon (SiOC). For example, the second encapsulation layer 117b may be prepared by an inkjet method, but is not limited thereto.

The third encapsulation layer 117c may be provided on the flexible substrate 110 on which the second encapsulation layer 117b is disposed so as to cover upper and side surfaces of the second encapsulation layer 117b and the first encapsulation layer 117a. Herein, the third encapsulation layer 117c may minimize or block the permeation of external moisture or oxygen into the first encapsulation layer 117a and the second encapsulation layer 117b. For example, the third encapsulation layer 117c may be made of an inorganic insulating material such as silicon nitride (SiNx), silicon oxide (SiOx), silicon oxynitride (SiON), or aluminum oxide (Al₂O₃).

The touch sensing layer may be disposed on the encapsulation layer 117. The touch sensing layer may include a touch electrode TE including a touch sensor metal TS and a bridge metal BM. Also, the touch sensing layer may include a touch insulating layer including a touch buffer layer 118a, a touch interlayer insulating layer 118b, and a touch planarization layer 118c.

For example, the touch buffer layer 118a may be disposed on the third encapsulation layer 117c, and the touch electrode TE may be disposed on the touch buffer layer 118a.

The touch electrode TE may include the touch sensor metal TS and the bridge metal BM located on different layers from each other. The touch interlayer insulating layer 118b may be disposed between the touch sensor metal TS and the bridge metal BM.

The touch buffer layer 118a and the touch interlayer insulating layer 118b may be disposed to eliminate a step at a position where the touch electrode TE is disposed and facilitate electrical insulation. Thus, the touch buffer layer 118a and the touch interlayer insulating layer 118b may be made of an inorganic material. For example, each of the touch buffer layer 118a and the touch interlayer insulating layer 118b may be configured by a single layer of silicon nitride (SiNx) or silicon oxide (SiOx) or a multi-layer thereof.

The touch planarization layer 118c is disposed on the touch interlayer insulating layer 118b and the touch sensor metal TS. The touch planarization layer 118c may be an organic layer to planarize and protect an upper portion of the touch interlayer insulating layer 118b. It may be flattened. For example, the touch planarization layer 118c may be made of an organic material such as acryl resin, epoxy resin, phenolic resin, polyamide resin, or polyimide resin. The touch electrode TE may have a mesh shape.

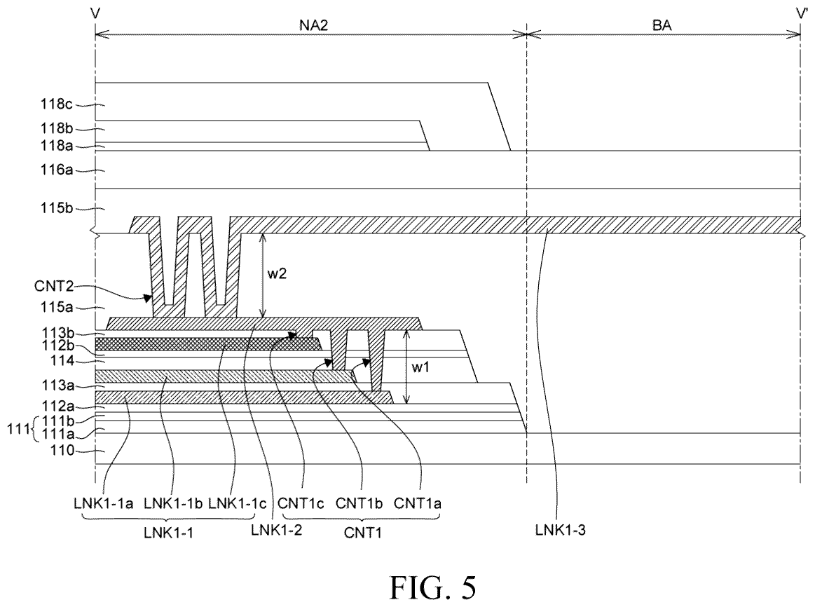

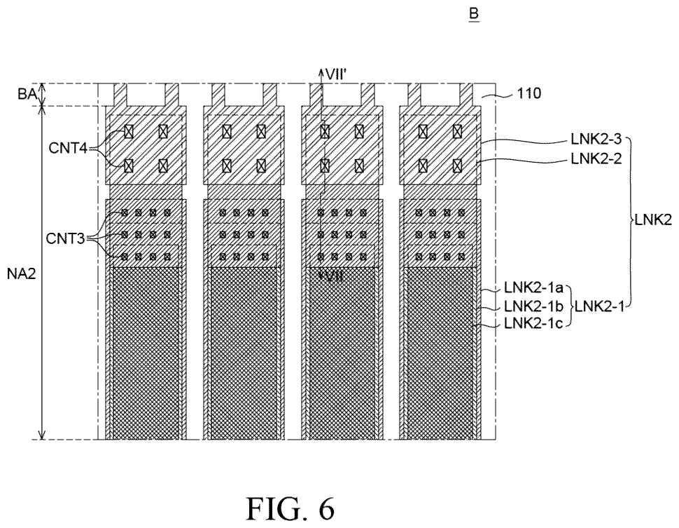

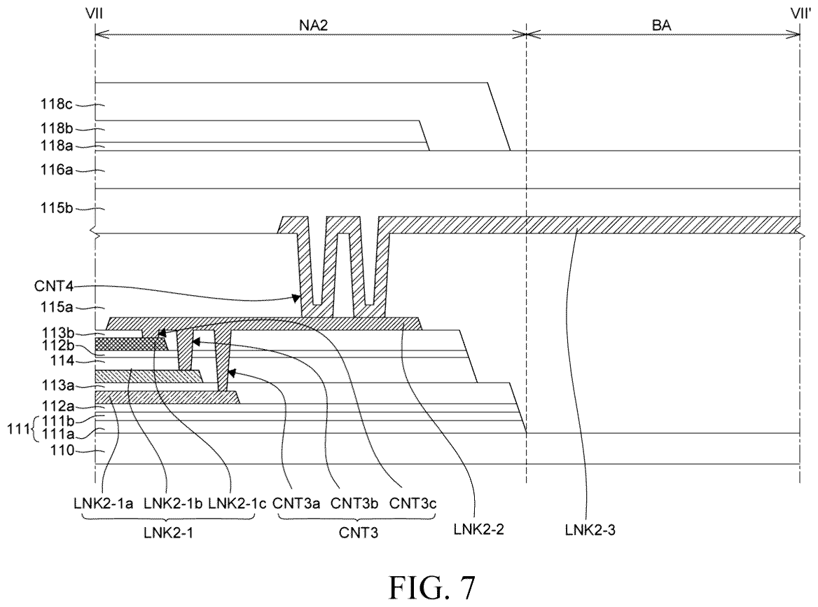

FIG. 4 is an enlarged plan view of an area A of FIG. 1. FIG. 5 is a cross-sectional view taken along the line V-V′ of FIG. 4. FIG. 6 is an enlarged plan view of an area B of FIG. 1. FIG. 7 is a cross-sectional view taken along the line VII-VII′ of FIG. 6. For convenience in explanation, FIG. 5 and FIG. 7 illustrate only the flexible substrate 110 and the plurality of link lines LNK. The area A in which the plurality of first link lines LNK1 is disposed will be described with reference to FIG. 5 and FIG. 7, and the area B in which the plurality of second link lines LNK2 is disposed will be described with reference to FIG. 6 and FIG. 7.

Referring to FIG. 1 and FIG. 4, the flexible substrate 110 of the display device 100 may include the display area AA and the non-display area NA. Also, the non-display area NA may include the first non-display area NA1, the second non-display area NA2, and the bending area BA.

The plurality of link lines LNK may be disposed in the first non-display area NA1, the second non-display area NA2, and the bending area BA. When the flexible substrate 110 and the display area AA correspond in shape to the variant corner regions, the plurality of link lines LNK may correspond in shape to the display area AA and the flexible substrate 110 in the variant corner regions.

The plurality of link lines LNK may include the plurality of first link lines LNK1 and the plurality of second link lines LNK2.

The plurality of first link lines LNK1 may connect the plurality of pads PAD to the gate driver GD. Specifically, the plurality of first link lines LNK1 may transmit signals for driving the gate driver GD from the plurality of first pads PAD1 to the gate driver GD. For example, the plurality of first link lines LNK1 may transmit a clock signal, a power signal, etc. to the gate driver GD. Thus, the first link line LNK1 may serve as a gate link line, but is not limited thereto.

Referring to FIG. 3 and FIG. 4, the plurality of first link lines LNK1 may include a plurality of 1-1-th link lines LNK1-1, a plurality of 1-2-th link lines LNK1-2, and a plurality of 1-3-th link lines LNK1-3. The plurality of 1-1-th link lines LNK1-1 and the plurality of 1-2-th link lines LNK1-2 may be disposed in the non-display area NA. Also, the plurality of 1-3-th link lines LNK1-3 may be disposed in the non-display area NA and the bending area BA.

The multi-buffer layer 111a, the active buffer layer 111b, and the first gate insulating layer 112a are disposed on the flexible substrate 110. Further, the plurality of 1-1-th link lines LNK1-1 is disposed on the multi-buffer layer 111a, the active buffer layer 111b, and the first gate insulating layer 112a. The plurality of 1-1-th link lines LNK1-1 may be connected to the gate driver GD.

Each of the plurality of 1-1-th link lines LNK1-1 may have a different polarity from another 1-1-th link line adjacent thereto. Thus, each of the plurality of first link lines LNK1 may also have a different polarity from another first link line LNK1 adjacent thereto. For example, when one of the plurality of 1-1-th link lines LNK1-1 has a positive (+) polarity, another 1-1-th link line LNK1-1 adjacent thereto may have a negative (−) polarity. Therefore, a voltage difference may occur between the plurality of 1-1-th link lines LNK1-1 adjacent to each other. Meanwhile, the plurality of 1-1-th link lines LNK1-1 may have the same polarity. In this case, there may be a considerably high voltage difference between the 1-1-th link lines LNK1-1 adjacent to each other.

The plurality of 1-1-th link lines LNK1-1 may include a plurality of sub-link lines LNK1-1a, LNK1-1b and LNK1-1c. Specifically, each of the plurality of 1-1-th link lines LNK1-1 may include the plurality of sub-link lines LNK1-1a, LNK1-1b and LNK1-1c with an insulating layer interposed therebetween. The plurality of sub-link lines LNK1-1a, LNK1-1b and LNK1-1c may include a first sub-link line LNK1-1a, a second sub-link line LNK1-1b, and a third sub-link line LNK1-1c.

The first sub-link line LNK1-1a of the plurality of 1-1-th link lines LNK1-1 is disposed on the multi-buffer layer 111a, the active buffer layer 111b, and the first gate insulating layer 112a. Also, the first sub-link line LNK1-1a may be simultaneously made of the same material and provided on the same layer as the first gate electrode G1, but is not limited thereto.

The first interlayer insulating layer 113a is disposed on the first sub-link line LNK1-1a of the plurality of 1-1-th link lines LNK1-1. Also, the second sub-link line LNK1-1b of the plurality of 1-1-th link lines LNK1-1 is disposed on the first interlayer insulating layer 113a. The second sub-link line LNK1-1b of the plurality of 1-1-th link lines LNK1-1 may be simultaneously made of the same material and provided on the same layer as the second capacitor electrode C2, but is not limited thereto.

The second gate insulating layer 112b and the second buffer layer 114 are disposed on the second sub-link line LNK1-1b of the plurality of 1-1-th link lines LNK1-1. Also, the third sub-link line LNK1-1c of the plurality of 1-1-th link lines LNK1-1 is disposed on the second gate insulating layer 112b and the second buffer layer 114. The third sub-link line LNK1-1c of the plurality of 1-1-th link lines LNK1-1 may be simultaneously made of the same material and provided on the same layer as the second gate electrode G2, but is not limited thereto.

The second interlayer insulating layer 113b is disposed on the plurality of 1-1-th link lines LNK1-1, and the plurality of 1-2-th link lines LNK1-2 is disposed on the second interlayer insulating layer 113b. The plurality of 1-2-th link lines LNK1-2 may be disposed for overlapping the plurality of 1-1-th link lines LNK1-1.

The plurality of 1-2-th link lines LNK1-2 may be respectively connected to the plurality of 1-1-th link lines LNK1-1 through a plurality of first contact holes CNT1 disposed in the first interlayer insulating layer 113a, the second gate insulating layer 112b, the second buffer layer 114, and the second interlayer insulating layer 113b. That is, the plurality of 1-2-th link lines LNK1-2 may be respectively connected to the first sub-link line LNK1-1a through a first contact hole CNT1a disposed in the first interlayer insulating layer 113a, the second gate insulating layer 112b, the second buffer layer 114, and the second interlayer insulating layer 113b. Further, the plurality of 1-2-th link lines LNK1-2 may be respectively connected to the second sub-link line LNK1-1b through a first contact hole CNT1b disposed in the second gate insulating layer 112b, the second buffer layer 114, and the second interlayer insulating layer 113b, and to the third sub-link line LNK1-1c through a first contact hole CNT1c disposed in the second interlayer insulating layer 113b.

The plurality of 1-2-th link lines LNK1-2 may be simultaneously made of the same material and provided on the same layer as the first source electrode S1, the first drain electrode D1, the second source electrode S2, and the second drain electrode D2, but is not limited thereto. For example, each of the plurality of 1-2-th link lines LNK1-2 may have a three-layer structure of titanium (Ti), aluminum (Al), and titanium (Ti), but is not limited thereto.

The first planarization layer 115a is disposed on the plurality of 1-2-th link lines LNK1-2, and the plurality of 1-3-th link lines LNK1-3 is disposed on the first planarization layer 115a. The plurality of 1-3-th link lines LNK1-3 may be respectively connected to the plurality of 1-2-th link lines LNK1-2 through a plurality of second contact holes CNT2 disposed in the first planarization layer 115a. The plurality of 1-3-th link lines LNK1-3 may be connected to the plurality of first pads PAD1.

The plurality of 1-3-th link lines LNK1-3 may be simultaneously made of the same material and provided on the same layer as the auxiliary electrode 145, but is not limited thereto. For example, each of the plurality of 1-3-th link lines LNK1-3 may have a three-layer structure of titanium (Ti), aluminum (Al), and titanium (Ti), but is not limited thereto.

The plurality of second contact holes CNT2 may be disposed more adjacent to the display area AA than the plurality of first contact holes CNT1. That is, the plurality of first contact holes CNT1 which electrically connects the plurality of 1-1-th link lines LNK1-1 to the plurality of 1-2-th link lines LNK1-2 may be disposed farther from the display area AA than the plurality of second contact holes CNT2 which electrically connects the plurality of 1-2-th link lines LNK1-2 to the plurality of 1-3-th link lines LNK1-3.

A longitudinal width w1 of the plurality of first contact holes CNT1 may be smaller than a longitudinal width w2 of the plurality of second contact holes CNT2. Herein, a longitudinal width of contact hole may refer to the distance from an upper surface of one or more insulating layers in which the contact hole is disposed to a lower surface thereof. The plurality of first contact holes CNT1 may be disposed in the first interlayer insulating layer 113a, the second gate insulating layer 112b, the second buffer layer 114, and the second interlayer insulating layer 113b, all of which are made of inorganic materials. However, the plurality of second contact holes CNT2 may be disposed in the first planarization layer 115a, which is made of an organic material. A layer made of an inorganic material has a much smaller thickness than a layer made of an organic material. Therefore, the longitudinal width w1 of the plurality of first contact holes CNT1 may be smaller than the longitudinal width w2 of the plurality of second contact holes CNT2.

The second planarization layer 115b, the bank 116a, the touch buffer layer 118a, the touch interlayer insulating layer 118b, and the touch planarization layer 118c may be disposed on the plurality of 1-3-th link lines LNK1-3.

Meanwhile, the multi-buffer layer 111a, the active buffer layer 111b, the first gate insulating layer 112a, the first interlayer insulating layer 113a, the second gate insulating layer 112b, the second buffer layer 114, and the second interlayer insulating layer 113b are disposed only in the second non-display area NA2, but not disposed in the bending area BA. This is to reduce stress in the bending area BA and suppress the occurrence of cracks in the insulating layers made of inorganic materials. That is, the touch insulating layers including the touch buffer layer 118a, the touch interlayer insulating layer 118b, and the touch planarization layer 118c entirely overlap the plurality of 1-1-th link lines LNK1-1 and the plurality of 1-2-th link lines LNK1-2. However, they are not disposed in the bending area BA. Therefore, they may overlap only a part of the plurality of 1-3-th link lines LNK1-3.

The plurality of second link lines LNK2 may connect the plurality of pads PAD to various lines disposed in the display area AA. Specifically, the plurality of second link lines LNK2 may transmit signals for driving the pixels disposed in the display area AA to various lines from the plurality of second pads PAD2. For example, the plurality of second link lines LNK2 may serve to transmit a data voltage, a power voltage, etc. to the display area AA. Thus, the plurality of second link line LNK2 may serve as a data link line or a power link line, but is not limited thereto.

Referring to FIG. 6 and FIG. 7, the plurality of second link lines LNK2 may include a plurality of 2-1-th link lines LNK2-1, a plurality of 2-2-th link lines LNK2-2, and a plurality of 2-3-th link lines LNK2-3. The plurality of 2-1-th link lines LNK2-1 and the plurality of 2-2-th link lines LNK2-2 may be disposed in the non-display area NA. Also, the plurality of 2-3-th link lines LNK2-3 may be disposed in the non-display area NA and the bending area BA.

The multi-buffer layer 111a, the active buffer layer 111b, and the first gate insulating layer 112a may be disposed on the flexible substrate 110. Also, the plurality of 2-1-th link lines LNK2-1 is disposed on the multi-buffer layer 111a, the active buffer layer 111b, and the first gate insulating layer 112a. The plurality of 2-1-th link lines LNK2-1 may be connected to various lines disposed in the display area AA.

There may be a very small voltage difference between each of the plurality of 2-1-th link lines LNK2-1 and another 2-1-th link line LNK2-1 adjacent thereto. For example, a voltage difference between signals transmitted by 2-1-th link lines LNK2-1 adjacent to each other among the plurality of 2-1-th link lines LNK2-1 may be lower than a voltage difference between signals transmitted by 1-1-th link lines LNK1-1 adjacent to each other among the plurality of 1-1-th link lines LNK1-1.

The plurality of 2-1-th link lines LNK2-1 may include a plurality of sub-link lines LNK2-1a, LNK2-1b and LNK2-1c. Specifically, each of the plurality of 2-1-th link lines LNK2-1 may include the plurality of sub-link lines LNK2-1a, LNK2-1b and LNK2-1c with an insulating layer interposed therebetween. The plurality of sub-link lines LNK2-1a, LNK2-1b and LNK2-1c may include a first sub-link line LNK2-1a, a second sub-link line LNK2-1b, and a third sub-link line LNK2-1c.

The first sub-link line LNK2-1a of the plurality of 2-1-th link lines LNK2-1 is disposed on the multi-buffer layer 111a, the active buffer layer 111b, and the first gate insulating layer 112a. Also, the first sub-link line LNK2-1a may be simultaneously made of the same material and provided on the same layer as the first gate electrode G1, but is not limited thereto.

The first interlayer insulating layer 113a is disposed on the first sub-link line LNK2-1a of the plurality of 2-1-th link lines LNK2-1. Also, the second sub-link line LNK2-1b of the plurality of 2-1-th link lines LNK2-1 is disposed on the first interlayer insulating layer 113a. The second sub-link line LNK2-1b of the plurality of 2-1-th link lines LNK2-1 may be simultaneously made of the same material and provided on the same layer as the second capacitor electrode C2, but is not limited thereto.

The second gate insulating layer 112b and the second buffer layer 114 are disposed on the second sub-link line LNK2-1b of the plurality of 2-1-th link lines LNK2-1. Also, the third sub-link line LNK2-1c of the plurality of 2-1-th link lines LNK2-1 is disposed on the second gate insulating layer 112b and the second buffer layer 114. The third sub-link line LNK2-1c of the plurality of 2-1-th link lines LNK2-1 may be simultaneously made of the same material and provided on the same layer as the second gate electrode G2, but is not limited thereto.

The second interlayer insulating layer 113b is disposed on the plurality of 2-1-th link lines LNK2-1, and the plurality of 2-2-th link lines LNK2-2 is disposed on the second interlayer insulating layer 113b. The plurality of 2-2-th link lines LNK2-2 may be disposed for overlapping the plurality of 2-1-th link lines LNK2-1.

The plurality of 2-2-th link lines LNK2-2 may be respectively connected to the plurality of 2-1-th link lines LNK2-1 through a plurality of third contact holes CNT3 disposed in the first interlayer insulating layer 113a, the second gate insulating layer 112b, the second buffer layer 114, and the second interlayer insulating layer 113b. That is, the plurality of 2-2-th link lines LNK2-2 may be respectively connected to the first sub-link line LNK2-1a through a third contact hole CNT3a disposed in the first interlayer insulating layer 113a, the second gate insulating layer 112b, the second buffer layer 114, and the second interlayer insulating layer 113b. Further, the plurality of 2-2-th link lines LNK2-2 may be respectively connected to the second sub-link line LNK2-1b through a third contact hole CNT3b disposed in the second gate insulating layer 112b, the second buffer layer 114, and the second interlayer insulating layer 113b, and to the third sub-link line LNK2-1c through a third contact hole CNT3c disposed in the second interlayer insulating layer 113b.

The plurality of 2-2-th link lines LNK2-2 may be simultaneously made of the same material and provided on the same layer as the first source electrode S1, the first drain electrode D1, the second source electrode S2, and the second drain electrode D2, but is not limited thereto. For example, each of the plurality of 2-2-th link lines LNK2-2 may have a three-layer structure of titanium (Ti), aluminum (Al), and titanium (Ti), but is not limited thereto.

The first planarization layer 115a is disposed on the plurality of 2-2-th link lines LNK2-2, and the plurality of 2-3-th link lines LNK2-3 is disposed on the first planarization layer 115a. The plurality of 2-3-th link lines LNK2-3 may be respectively connected to the plurality of 2-2-th link lines LNK2-2 through a plurality of fourth contact holes CNT4 disposed in the first planarization layer 115a. The plurality of 2-3-th link lines LNK2-3 may be connected to the plurality of second pads PAD2.

The plurality of 2-3-th link lines LNK2-3 may be simultaneously made of the same material and provided on the same layer as the auxiliary electrode 145, but is not limited thereto. For example, each of the plurality of 2-3-th link lines LNK2-3 may have a three-layer structure of titanium (Ti), aluminum (Al), and titanium (Ti), but is not limited thereto.

The plurality of fourth contact holes CNT4 may be disposed farther from the display area AA than the plurality of third contact holes CNT3. That is, the plurality of third contact holes CNT3 which electrically connects the plurality of 2-1-th link lines LNK2-1 to the 2-2-th link line LNK2-2 may be disposed more adjacent to the display area AA than the plurality of fourth contact holes CNT4 which electrically connects the plurality of 2-2-th link lines LNK2-2 to the plurality of 2-3-th link lines LNK2-3.

The plurality of second contact holes CNT2 is disposed more adjacent to the display area AA than the plurality of first contact holes CNT1. Also, the plurality of fourth contact holes CNT4 is disposed farther from the display area AA than the plurality of third contact holes CNT3. Therefore, the plurality of 1-1-th link lines LNK1-1 may be disposed further outside the flexible substrate 110 than the plurality of 2-1-th link lines LNK2-1.

Meanwhile, the multi-buffer layer 111a, the active buffer layer 111b, the first gate insulating layer 112a, the first interlayer insulating layer 113a, the second gate insulating layer 112b, the second buffer layer 114, and the second interlayer insulating layer 113b are disposed only in the second non-display area NA2, but not disposed in the bending area BA. This is to reduce stress in the bending area BA and suppress the occurrence of cracks in the insulating layers made of inorganic materials. That is, the touch insulating layers including the touch buffer layer 118a, the touch interlayer insulating layer 118b, and the touch planarization layer 118c entirely overlap the plurality of 2-1-th link lines LNK2-1 and the plurality of 2-2-th link lines LNK2-2. However, they are not disposed in the bending area BA. Therefore, they may overlap only a part of the plurality of 2-3-th link lines LNK2-3.

In a general display device, various inorganic layers are used to block the permeation of moisture. However, such inorganic layers have lower flexibility than organic layers and thus show brittleness, which has the tendency to fracture. Accordingly, in a display device including a bezel area to be bent, inorganic layers are not disposed in the bending area to suppress the permeation of moisture into the display device from the bending area through cracks or seams in the inorganic layers caused by stress in the bending area. As such, the inorganic layers may be designed to suppress the occurrence of cracks or seams in the bending area. However, in the bending area, only organic layers which are relatively vulnerable to the permeation of moisture are disposed. Therefore, moisture may easily permeate into the display device from the bending area. Also, the permeation of moisture may be accelerated in high-temperature and/or high-humidity environments.

Particularly, each link line disposed in the bending area and a non-display area may have a three-layer structure of titanium (Ti), aluminum (Al), and titanium (Ti). In this case, aluminum (Al) is a metal material which has a low resistance, but is vulnerable to moisture. That is, aluminum (Al) is easily oxidized and corroded and thus easily brittle, and it may be very vulnerable to the permeation of moisture. However, the use of an aluminum material to maintain a low resistance is important for the design of link lines.

Meanwhile, an inorganic layer generally used has a very small thickness, whereas an organic layer has a much greater thickness than the inorganic layer. Accordingly, if lines or electrodes are connected through a contact hole disposed in the inorganic layer, the probability of occurrence of cracks or seams in the contact hole is very low. However, if lines or electrodes are connected through a contact hole disposed in the organic layer, there may be a steep step change between the lines or electrodes disposed in the contact hole because the contact hole is deep. Accordingly, cracks or seams may occur in the lines or electrodes disposed in the contact hole. If the lines or electrodes contain a material such as aluminum (Al), the aluminum is easily oxidized or corroded, which may result in poor electrical connection between the lines or electrodes. Therefore, a resistance in the lines or electrodes may increase, which may result in a defect in reliability of the display device, such as abnormal operation or abnormal display.

Also, the organic layer may contain relatively more moisture than the inorganic layer. Thus, the lines or electrodes disposed in the contact hole in the organic layer may be exposed to more moisture than the lines or electrodes disposed in the contact hole in the inorganic layer. Further, when an electric field is applied to the lines or electrodes disposed in the contact hole, ions from the organic layer reach the lines or electrodes, and, thus, the lines or electrodes are more likely to be oxidized or corroded. Particularly, as a difference in voltage transmitted between the lines or electrodes adjacent to each other increases, the intensity of an electric field to be applied increases. Therefore, the oxidation or corrosion may be accelerated.

Particularly, in the currently used contact hole structure, the contact hole disposed in the organic layer is more adjacent to the bezel area than the contact hole disposed in the inorganic layer. Such oxidation or corrosion may be more likely to occur in the contact hole disposed in the organic layer. Thus, it is possible to consider a method of increasing the distance between the contact hole disposed in the organic layer and the bezel area. However, this method may cause an increase of the bezel area.

Thus, in the display device 100 according to an example embodiment of the present disclosure, the plurality of second contact holes CNT2 is disposed more adjacent to the display area AA than the plurality of first contact holes CNT1. Therefore, it is possible to suppress oxidation or corrosion of the 1-3-th link line LNK1-3 disposed in the plurality of second contact holes CNT2. The plurality of first contact holes CNT1 which connects the plurality of 1-1-th link lines LNK1-1 to the 1-2-th link line LNK1-2 is disposed in the inorganic layer. Also, the plurality of second contact holes CNT2 which connects the plurality of 1-2-th link lines LNK1-2 to the plurality of 1-3-th link lines LNK1-3 is disposed in the organic layer. Thus, the longitudinal width w1 of the plurality of first contact holes CNT1 may be smaller than the longitudinal width w2 of the plurality of second contact holes CNT2. Therefore, the 1-3-th link line LNK1-3 disposed in the plurality of second contact holes CNT2 may be oxidized or corroded in the plurality of second contact holes CNT2. Particularly, the plurality of 1-1-th link lines LNK1-1 may serve as gate link lines connected to the gate driver GD. Each 1-1-th link line LNK1-1 may have a different polarity from another 1-1-th link line adjacent thereto, or there may be a relatively high voltage difference between the 1-1-th link lines LNK1-1. Therefore, the plurality of 1-1-th link lines LNK1-1 may be easily oxidized or corroded. Thus, in the display device according to an example embodiment of the present disclosure, the plurality of second contact holes CNT2 disposed in the organic layer is disposed farther from the bending area BA than the plurality of first contact holes CNT1 disposed in the inorganic layer. Therefore, it is possible to suppress oxidation or corrosion of the plurality of 1-3-th link lines LNK1-3 in the plurality of second contact holes CNT2 disposed in the organic layer. Thus, it is possible to minimize a resistance increase in the plurality of 1-3-th link lines LNK1-3 and also possible to suppress a defect in reliability of the display device 100, such as abnormal operation or abnormal display. Therefore, the reliability of the display device 100 may be improved.

Also, in the display device 100 according to an example embodiment of the present disclosure, it is possible to suppress oxidation or corrosion of the 1-3-th link line LNK1-3 without an increase in size of the bezel area. In a central area of the display device 100, the plurality of fourth contact holes CNT4 is disposed farther from the display area AA than the plurality of third contact holes CNT3 without a change in design. However, the plurality of second contact holes CNT2 may be disposed more adjacent to the display area AA than the plurality of first contact holes CNT1 only on both sides of the display device 100, i.e., only in the area in which the first link lines LNK1 are disposed. That is, the distance between the plurality of second contact holes CNT2 disposed in the organic layer and the bending area BA may be increased by changing positions of the contact holes. Thus, in the display device 100 according to an example embodiment of the present disclosure, the distance between the plurality of second contact holes CNT2 and the bending area BA may be increased without an increase in size of the bezel area. Therefore, the reliability of the display device 100 may be improved.

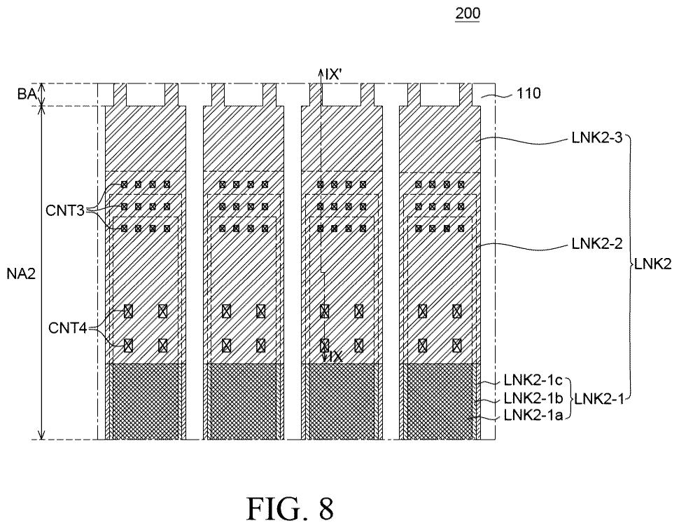

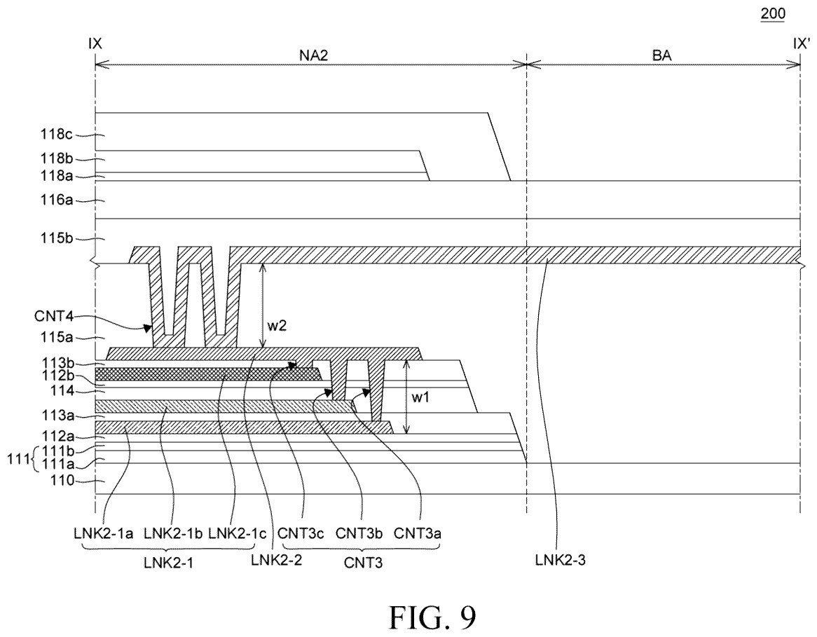

FIG. 8 is an enlarged plan view of a display device according to another example embodiment of the present disclosure. FIG. 9 is a cross-sectional view taken along the line IX-IX′ of FIG. 8. The display device shown in FIG. 8 and FIG. 9 is substantially the same as the display device shown in FIG. 1 through FIG. 7 except a connection between the second link lines LNK2 in the area B. Therefore, repeated description is omitted.

The plurality of second link lines LNK2 may connect the plurality of pads PAD to various lines disposed in the display area AA. Specifically, the plurality of second link lines LNK2 may transmit signals for driving the pixels disposed in the display area AA to various lines from the plurality of second pads PAD2. For example, the plurality of second link lines LNK2 may serve to transmit a data voltage, a power voltage, etc. to the display area AA. Thus, the second link line LNK2 may serve as a data link line or a power link line, but is not limited thereto.

Referring to FIG. 8 and FIG. 9, the plurality of second link lines LNK2 may include the plurality of 2-1-th link lines LNK2-1, the plurality of 2-2-th link lines LNK2-2, and the plurality of 2-3-th link lines LNK2-3. The plurality of 2-1-th link lines LNK2-1 and the plurality of 2-2-th link lines LNK2-2 may be disposed in the non-display area NA. Also, the plurality of 2-3-th link lines LNK2-3 may be disposed in the non-display area NA and the bending area BA.

The multi-buffer layer 111a, the active buffer layer 111b, and the first gate insulating layer 112a are disposed on the flexible substrate 110. Also, the plurality of 2-1-th link lines LNK2-1 is disposed on the multi-buffer layer 111a, the active buffer layer 111b, and the first gate insulating layer 112a. The plurality of 2-1-th link lines LNK2-1 may be connected to various lines disposed in the display area AA.

There may be a considerably low voltage difference between signals transmitted by 2-1-th link lines LNK2-1 adjacent to each other among the plurality of 2-1-th link lines LNK2-1. For example, a voltage difference between signals transmitted by 2-1-th link lines LNK2-1 adjacent to each other among the plurality of 2-1-th link lines LNK2-1 may be lower than a voltage difference between signals transmitted by 1-1-th link lines LNK1-1 adjacent to each other among the plurality of 1-1-th link lines LNK1-1.

The plurality of 2-1-th link lines LNK2-1 may include the plurality of sub-link lines LNK2-1a, LNK2-1b and LNK2-1c. Specifically, each of the plurality of 2-1-th link lines LNK2-1 may include the plurality of sub-link lines LNK2-1a, LNK2-1b and LNK2-1c with an insulating layer interposed therebetween. The plurality of sub-link lines LNK2-1a, LNK2-1b and LNK2-1c may include the first sub-link line LNK2-1a, the second sub-link line LNK2-1b, and the third sub-link line LNK2-1c.

The first sub-link line LNK2-1a of the plurality of 2-1-th link lines LNK2-1 is disposed on the multi-buffer layer 111a, the active buffer layer 111b, and the first gate insulating layer 112a. Also, the first sub-link line LNK2-1a may be simultaneously made of the same material and provided on the same layer as the first gate electrode G1, but is not limited thereto.

The first interlayer insulating layer 113a is disposed on the first sub-link line LNK2-1a of the plurality of 2-1-th link lines LNK2-1. Also, the second sub-link line LNK2-1b of the plurality of 2-1-th link lines LNK2-1 is disposed on the first interlayer insulating layer 113a. The second sub-link line LNK2-1b of the plurality of 2-1-th link lines LNK2-1 may be simultaneously made of the same material and provided on the same layer as the second capacitor electrode C2, but is not limited thereto.

The second gate insulating layer 112b and the second buffer layer 114 are disposed on the second sub-link line LNK2-1b of the plurality of 2-1-th link lines LNK2-1. Also, the third sub-link line LNK2-1c of the plurality of 2-1-th link lines LNK2-1 is disposed on the second gate insulating layer 112b and the second buffer layer 114. The third sub-link line LNK2-1c of the plurality of 2-1-th link lines LNK2-1 may be simultaneously made of the same material and provided on the same layer as the second gate electrode G2, but is not limited thereto.

The second interlayer insulating layer 113b is disposed on the plurality of 2-1-th link lines LNK2-1, and the plurality of 2-2-th link lines LNK2-2 is disposed on the second interlayer insulating layer 113b. The plurality of 2-2-th link lines LNK2-2 may be disposed for overlapping the plurality of 2-1-th link lines LNK2-1.

The plurality of 2-2-th link lines LNK2-2 may be respectively connected to the plurality of 2-1-th link lines LNK2-1 through the plurality of third contact holes CNT3 disposed in the first interlayer insulating layer 113a, the second gate insulating layer 112b, the second buffer layer 114, and the second interlayer insulating layer 113b. That is, the plurality of 2-2-th link lines LNK2-2 may be respectively connected to the first sub-link line LNK2-1a through the third contact hole CNT3a disposed in the first interlayer insulating layer 113a, the second gate insulating layer 112b, the second buffer layer 114, and the second interlayer insulating layer 113b. Further, the plurality of 2-2-th link lines LNK2-2 may be respectively connected to the second sub-link line LNK2-1b through the third contact hole CNT3b disposed in the second gate insulating layer 112b, the second buffer layer 114, and the second interlayer insulating layer 113b, and to the third sub-link line LNK2-1c through the third contact hole CNT3c disposed in the second interlayer insulating layer 113b.

The plurality of 2-2-th link lines LNK2-2 may be simultaneously made of the same material and provided on the same layer as the first source electrode S1, the first drain electrode D1, the second source electrode S2, and the second drain electrode D2, but is not limited thereto. For example, each of the plurality of 2-2-th link lines LNK2-2 may have a three-layer structure of titanium (Ti), aluminum (Al), and titanium (Ti), but is not limited thereto.

The first planarization layer 115a is disposed on the plurality of 2-2-th link lines LNK2-2, and the plurality of 2-3-th link lines LNK2-3 is disposed on the first planarization layer 115a. The plurality of 2-3-th link lines LNK2-3 may be respectively connected to the plurality of 2-2-th link lines LNK2-2 through the plurality of fourth contact holes CNT4 disposed in the first planarization layer 115a. The plurality of 2-3-th link lines LNK2-3 may be connected to the plurality of second pads PAD2.

The plurality of 2-3-th link lines LNK2-3 may be simultaneously made of the same material and provided on the same layer as the auxiliary electrode 145, but is not limited thereto. For example, each of the plurality of 2-3-th link lines LNK2-3 may have a three-layer structure of titanium (Ti), aluminum (Al), and titanium (Ti), but is not limited thereto.

The plurality of fourth contact holes CNT4 may be disposed farther from the display area AA than the plurality of third contact holes CNT3. That is, the plurality of third contact holes CNT3 which electrically connects the plurality of 2-1-th link lines LNK2-1 to the 2-2-th link line LNK2-2 may be disposed more adjacent to the display area AA than the plurality of fourth contact holes CNT4 which electrically connects the plurality of 2-2-th link lines LNK2-2 to the plurality of 2-3-th link lines LNK2-3.

The plurality of fourth contact holes CNT4 is disposed more adjacent to the display area AA than the plurality of third contact holes CNT3. Also, the plurality of third contact holes CNT3 is disposed farther from the display area AA than the plurality of fourth contact holes CNT4. Therefore, the plurality of 1-1-th link lines LNK1-1 may be disposed at positions corresponding to the plurality of 2-1-th link lines LNK2-1 on the plane.

In a display device 200 according to another example embodiment of the present disclosure, the plurality of fourth contact holes CNT4 is disposed more adjacent to the display area AA than the plurality of third contact holes CNT3. Therefore, it is possible to suppress oxidation or corrosion of the 2-3-th link line LNK2-3 disposed in the plurality of fourth contact holes CNT4. That is, in the display device according to another example embodiment of the present disclosure, the plurality of fourth contact holes CNT4 disposed in the organic layer is disposed farther from the bending area BA than the plurality of third contact holes CNT3 disposed in the inorganic layer. Therefore, it is possible to suppress oxidation or corrosion of the plurality of 2-3-th link lines LNK2-3 in the plurality of fourth contact holes CNT4 disposed in the organic layer. Thus, it is possible to minimize a resistance increase in the plurality of 2-3-th link lines LNK2-3 and also possible to suppress a defect in reliability of the display device 200, such as abnormal operation or abnormal display. Therefore, the reliability of the display device 200 may be improved.

Also, in the display device 200 according to another example embodiment of the present disclosure, the plurality of fourth contact holes CNT4 is disposed more adjacent to the display area AA than the plurality of third contact holes CNT3. Thus, it is possible to suppress oxidation or corrosion of the 2-3-th link line LNK2-3 disposed in the plurality of fourth contact holes CNT4. Each of the plurality of second link lines LNK2 serves as a data link line or a power link line. A voltage difference between the second link lines LNK2 adjacent to each other may be lower than a voltage difference between the plurality of first link lines LNK1. Thus, the second link lines LNK2 may have a higher resistance to oxidation or corrosion than the plurality of first link lines LNK1. However, the plurality of 2-3-th link lines LNK2-3 of the plurality of second link lines LNK2 is disposed in the fourth contact hole CNT4 disposed in the organic layer. Therefore, oxidation or corrosion may occur in the plurality of 2-3-th link lines LNK2-3. Thus, in the display device 200 according to another example embodiment of the present disclosure, the plurality of fourth contact holes CNT4 disposed in the organic layer is disposed farther from the bending area BA than the plurality of third contact holes CNT3 disposed in the inorganic layer. Therefore, it is possible to suppress oxidation or corrosion of the plurality of 2-3-th link lines LNK2-3 in the plurality of fourth contact holes CNT4 disposed in the organic layer. Thus, it is possible to minimize a resistance increase in the plurality of 2-3-th link lines LNK2-3 and also possible to suppress a defect in reliability of the display device 200, such as abnormal operation or abnormal display. Therefore, the reliability of the display device 200 may be improved.

Further, in the display device 200 according to another example embodiment of the present disclosure, it is possible to suppress oxidation or corrosion of the 2-3-th link line LNK2-3 without an increase in size of the bezel area. That is, the distance between the plurality of fourth contact holes CNT4 disposed in the organic layer and the distance between the plurality of fourth contact holes CNT4 and the bending area BA may be increased just by changing positions of the contact holes. Thus, in the display device 200 according to another example embodiment of the present disclosure, the distance between the plurality of fourth contact holes CNT4 and the distance between the plurality of fourth contact holes CNT4 and the bending area BA may be increased without an increase in size of the bezel area. Therefore, the reliability of the display device 200 may be improved.

The example embodiments of the present disclosure can also be described as follows:

According to an aspect of the present disclosure, a display device comprises a flexible substrate; a display area; a non-display area; a bending area extending from the non-display area; a plurality of 1-1-th link lines disposed on the flexible substrate in the non-display area; one or more insulating layers disposed on the plurality of 1-1-th link lines; a plurality of 1-2-th link lines respectively connected to the plurality of 1-1-th link lines through a plurality of first contact holes disposed in the one or more insulating layers; a first planarization layer disposed on the plurality of 1-2-th link lines; a plurality of 1-3-th link lines respectively connected to the plurality of 1-2-th link lines through a plurality of second contact holes disposed in the first planarization layer; and a plurality of first pads connected to the plurality of 1-3-th link lines, wherein the plurality of second contact holes is disposed more adjacent to the display area than the plurality of first contact holes.

The one or more insulating layers may be made of inorganic materials, and the first planarization layer may be made of an organic material.

A longitudinal width of the plurality of first contact holes may be smaller than a longitudinal width of the plurality of second contact holes.

The display device may further comprise a gate driver disposed in the non-display area, wherein the plurality of 1-1-th link lines may be connected to the gate driver.

A signal applied to each of the plurality of 1-1-th link lines may have a different polarity from a signal applied to another 1-1-th link line adjacent thereto.

At least one of the plurality of 1-1-th link lines may include a plurality of sub-link lines disposed on different layers from each other and connected to the same 1-2-th link line of the plurality of 1-2-th link lines.

The display device may further comprise a plurality of 2-1-th link lines disposed under the one or more insulating layers in the non-display area; a plurality of 2-2-th link lines disposed between the one or more insulating layers and the first planarization layer, and respectively connected to the plurality of 2-1-th link lines through a plurality of third contact holes disposed in the one or more insulating layers; a plurality of 2-3-th link lines respectively connected to the plurality of 2-2-th link lines through a plurality of fourth contact holes disposed in the first planarization layer; and a plurality of second pads connected to the plurality of 2-3-th link lines, wherein the plurality of third contact holes may be disposed more adjacent to the display area than the plurality of fourth contact holes.

Each of the plurality of 2-1-th link lines, the plurality of 2-2-th link lines, and the plurality of 2-3-th link lines may serve as a data link line or a power link line.

The plurality of 1-1-th link lines may be disposed further outside the flexible substrate than the plurality of 2-1-th link lines.

The display device may further comprise a plurality of 2-1-th link lines disposed under the one or more insulating layers in the non-display area; a plurality of 2-2-th link lines disposed between the one or more insulating layers and the first planarization layer, and respectively connected to the plurality of 2-1-th link lines through a plurality of third contact holes disposed in the one or more insulating layers; a plurality of 2-3-th link lines respectively connected to the plurality of 2-2-th link lines through a plurality of fourth contact holes disposed in the first planarization layer; and a plurality of second pads connected to the plurality of 2-3-th link lines, the plurality of fourth contact holes may be disposed more adjacent to the display area than the plurality of third contact holes.

The plurality of 1-1-th link lines and the plurality of 1-2-th link lines may be disposed in the non-display area, and the plurality of 1-3-th link lines may be disposed in the non-display area and the bending area.

The display device may further comprise a plurality of light emitting elements disposed on the flexible substrate in the display area; an encapsulation layer disposed on the plurality of light emitting elements; and a touch insulating layer disposed on the encapsulation layer, wherein the plurality of 1-1-th link lines and the plurality of 1-2-th link lines may entirely overlap the touch insulating layer.

The touch insulating layer may be disposed in the non-display area among the non-display area and the bending area, and may overlap only a part of the plurality of 1-3-th link lines.

The above description has been presented to enable any person skilled in the art to make, use and practice the technical features of the present disclosure, and has been provided in the context of one or more particular example applications and their example requirements. Various modifications, additions and substitutions to the described embodiments will be readily apparent to those skilled in the art, and the principles described herein may be applied to other embodiments and applications without departing from the scope of the present disclosure. The above description and the accompanying drawings provide examples of the technical features of the present disclosure for illustrative purposes. In other words, the disclosed embodiments are intended to illustrate the scope of the technical features of the present disclosure. Thus, the scope of the present disclosure is not limited to the embodiments shown, but is to be accorded the widest scope consistent with the claims. The scope of protection of the present disclosure should be construed based on the following claims, and all technical features within the scope of equivalents thereof should be construed as being included within the scope of the present disclosure.

What is claimed is:

1. A display device, comprising:
a flexible substrate;
a display area;
a non-display area;
a bending area extending from the non-display area;
a plurality of 1-1-th link lines disposed on the flexible substrate in the non-display area;
one or more insulating layers disposed on the plurality of 1-1-th link lines;
a plurality of 1-2-th link lines respectively connected to the plurality of 1-1-th link lines through a plurality of first contact holes disposed in the one or more insulating layers;
a first planarization layer disposed on the plurality of 1-2-th link lines;
a plurality of 1-3-th link lines respectively connected to the plurality of 1-2-th link lines through a plurality of second contact holes disposed in the first planarization layer; and
a plurality of first pads connected to the plurality of 1-3-th link lines,
wherein the plurality of second contact holes is disposed more adjacent to the display area than the plurality of first contact holes.

2. The display device according to claim 1, wherein the one or more insulating layers are made of inorganic materials, and
the first planarization layer is made of an organic material.

3. The display device according to claim 2, wherein a longitudinal width of the plurality of first contact holes is smaller than a longitudinal width of the plurality of second contact holes.

4. The display device according to claim 1, further comprising:
a gate driver disposed in the non-display area,
wherein the plurality of 1-1-th link lines is connected to the gate driver.

5. The display device according to claim 4, wherein a signal for being applied to each of the plurality of 1-1-th link lines has a different polarity from a signal for being applied to another 1-1-th link line adjacent thereto.

6. The display device according to claim 4, wherein at least one of the plurality of 1-1-th link lines includes a plurality of sub-link lines disposed on different layers from each other and connected to the same 1-2-th link line of the plurality of 1-2-th link lines.

7. The display device according to claim 1, further comprising:
a plurality of 2-1-th link lines disposed under the one or more insulating layers in the non-display area;
a plurality of 2-2-th link lines disposed between the one or more insulating layers and the first planarization layer, and respectively connected to the plurality of 2-1-th link lines through a plurality of third contact holes disposed in the one or more insulating layers;
a plurality of 2-3-th link lines respectively connected to the plurality of 2-2-th link lines through a plurality of fourth contact holes disposed in the first planarization layer; and
a plurality of second pads connected to the plurality of 2-3-th link lines,
wherein the plurality of third contact holes is disposed more adjacent to the display area than the plurality of fourth contact holes.

8. The display device according to claim 7, wherein each of the plurality of 2-1-th link lines, the plurality of 2-2-th link lines, and the plurality of 2-3-th link lines serves as a data link line or a power link line.

9. The display device according to claim 7, wherein the plurality of 1-1-th link lines is disposed further outside the flexible substrate than the plurality of 2-1-th link lines.

10. The display device according to claim 4, further comprising:
a plurality of 2-1-th link lines disposed under the one or more insulating layers in the non-display area;
a plurality of 2-2-th link lines disposed between the one or more insulating layers and the first planarization layer, and respectively connected to the plurality of 2-1-th link lines through a plurality of third contact holes disposed in the one or more insulating layers;
a plurality of 2-3-th link lines respectively connected to the plurality of 2-2-th link lines through a plurality of fourth contact holes disposed in the first planarization layer; and
a plurality of second pads connected to the plurality of 2-3-th link lines,
wherein the plurality of fourth contact holes is disposed more adjacent to the display area than the plurality of third contact holes.

11. The display device according to claim 1, wherein the plurality of 1-1-th link lines and the plurality of 1-2-th link lines are disposed in the non-display area, and
the plurality of 1-3-th link lines is disposed in the non-display area and the bending area.

12. The display device according to claim 1, further comprising:
a plurality of light emitting elements disposed on the flexible substrate in the display area;
an encapsulation layer disposed on the plurality of light emitting elements; and
a touch insulating layer disposed on the encapsulation layer,
wherein the plurality of 1-1-th link lines and the plurality of 1-2-th link lines entirely overlap the touch insulating layer.

13. The display device according to claim 12, wherein the touch insulating layer is disposed in the non-display area among the non-display area and the bending area, and overlaps only a part of the plurality of 1-3-th link lines.

14. The display device according to claim 7, wherein the plurality of 2-1-th link lines and the plurality of 2-2-th link lines are disposed in the non-display area, and
the plurality of 2-3-th link lines is disposed in the non-display area and the bending area.

15. The display device according to claim 10, wherein the plurality of 2-1-th link lines and the plurality of 2-2-th link lines are disposed in the non-display area, and
the plurality of 2-3-th link lines is disposed in the non-display area and the bending area.
